(19) United States
(12) Patent Application Publication
(10) Pub. No.: US 2026/0130228 A1
(43) Pub. Date: May 7, 2026

(54) METHOD FOR FABRICATING SEMICONDUCTOR STRUCTURE

(71) Applicant: Taiwan Semiconductor Manufacturing Company, Ltd., Hsinchu (TW)

(72) Inventor: Chien-Hsun LIN, Kaohsiung City (TW)

(73) Assignee: Taiwan Semiconductor Manufacturing Company, Ltd., Hsinchu (TW)

(21) Appl. No.: 18/939,972

(22) Filed: Nov. 7, 2024

(51) Int. Cl. H01L 23/544; H01L 21/66; H01L 21/8234; H01L 23/00

(52) U.S. Cl. CPC H10W 46/00; H10D 84/0149; H10D 84/0151; H10D 84/038; H10P 74/273; H10W 42/121; H10D 84/0158; H10W 46/503; H10W 46/507

(57) ABSTRACT

A method for fabricating a semiconductor structure is provided. The method includes providing a plurality of chip regions on a substrate. The method includes forming a plurality of scribe line regions among the chip regions on the substrate. The scribe line regions each include a testing region having a plurality of testing patterns and a dicing region around the test region. The dicing region has a dummy band adjacent to the testing region, and a plurality of dummy patterns are formed in the dummy band and electrically isolated from the testing patterns. The method also includes separating the chip regions along the dicing region of the scribe line regions.

### BACKGROUND

Semiconductor devices are used in a variety of electronic applications, such as personal computers, cell phones, digital cameras, and other electronic equipment. Semiconductor devices are typically fabricated by sequentially depositing insulating or dielectric layers, conductive layers, and semiconductive layers of material over a semiconductor substrate, and patterning the various material layers using lithography to form circuit components and elements thereon. Many integrated circuits are typically manufactured on a single semiconductor wafer, and individual dies on the wafer are singulated by sawing between the integrated circuits along a scribe line. The individual dies are typically packaged separately, in multi-chip modules, for example, or in other types of packaging.

Although existing methods of fabricating semiconductor structures have generally been adequate for their intended purposes, they have not been entirely satisfactory in all respects.

### BRIEF DESCRIPTION OF THE DRAWINGS

Aspects of the present disclosure are best understood from the following detailed description when read with the accompanying figures. It should be noted that, in accordance with standard practice in the industry, various features are not drawn to scale. In fact, the dimensions of the various features may be arbitrarily increased or reduced for clarity of discussion.

FIG. 1 illustrates a schematic view of the semiconductor structure in accordance with some embodiments.

FIG. 2A illustrates a partial cross-sectional view of the semiconductor structure in accordance with some embodiments.

FIG. 2B illustrates an enlarged view of the region A shown in FIG. 3A in accordance with some embodiments.

FIG. 3A illustrates a partial cross-sectional view of the semiconductor structure in accordance with some embodiments.

FIG. 3B illustrates an enlarged view of the region B shown in FIG. 4A in accordance with some embodiments.

FIG. 4 illustrates an enlarged view of the dummy band and the seal ring shown in FIGS. 2A and 2B in accordance with some embodiments.

FIG. 5 illustrates an enlarged view of the dummy band and the testing region shown in FIGS. 2A and 2B in accordance with some embodiments.

FIGS. 6A through 6J illustrates cross-sectional views of intermediate steps during a process for fabricating a semiconductor structure in accordance with some embodiments.

FIG. 7 illustrates a schematic top view of the semiconductor structure in accordance with some embodiments.

FIG. 8 illustrates a partial cross-sectional view of the semiconductor structure in accordance with some embodiments.

FIGS. 9A through 9C illustrates schematic views of cut patterns in the semiconductor structure in accordance with some embodiments.

### DETAILED DESCRIPTION

The following disclosure provides many different embodiments, or examples, for implementing different features of the subject matter provided. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Some variations of the embodiments are described. Throughout the various views and illustrative embodiments, like reference numbers are used to designate like elements. It should be understood that additional operations can be provided before, during, and after the method, and some of the operations described can be replaced or eliminated for other embodiments of the method.

Embodiments of methods for fabricating the semiconductor structure are provided. The method includes forming a plurality of scribe lines among the chips on the substrate. The scribe lines each include a testing region and a dicing region around the testing region. Generally, the dicing region includes a wide empty area for the separation process. However, such empty area may be over-polished (or dishing) during the planarization processes, causing negative impact to the topography of neighboring test patterns in the testing region or even the chips. Thus, abnormal data may be obtained during electrical tests, degrading the yield of the semiconductor structure. In order to solve the dishing issue, the dicing region has a dummy band adjacent to the testing region, and a plurality of dummy patterns are formed in the dummy band and electrically isolated from the testing region. As a result, the dummy patterns in the dummy band may help to improve the surface topography after preforming planarization processes during the manufacturing process of the semiconductor device.

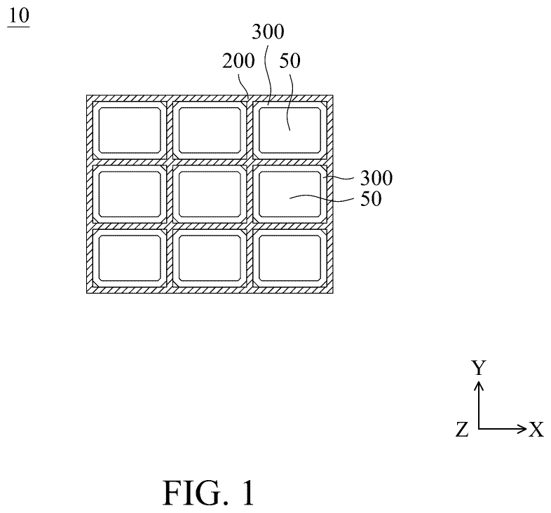

FIG. 1 illustrates a schematic view of the semiconductor structure 10 in accordance with some embodiments. As shown in FIG. 1, the semiconductor structure 10 includes a plurality of chip regions 50 and a plurality of scribe line regions 200 among the chip regions 50. In some embodiments, each of the chip regions 50 is surrounded by a seal ring 300 for protecting damages during dicing. The scribe line regions 200 are disposed for subsequent separation process so as to obtain individual chips. The detailed structure of the scribe line regions 200 will be further discussed below.

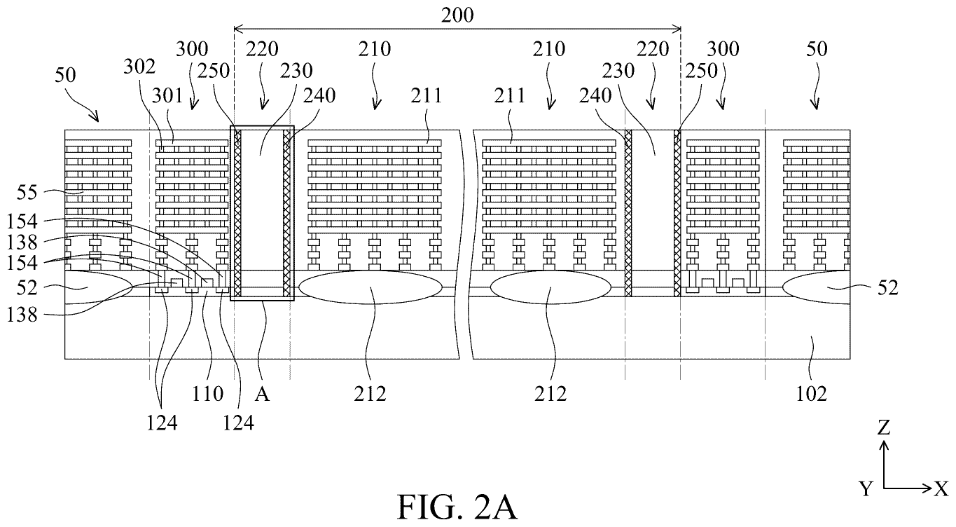

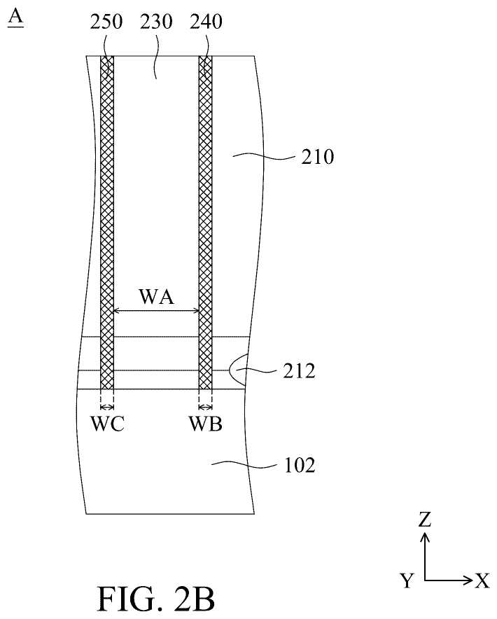

FIG. 2A illustrates a partial cross-sectional view of the semiconductor structure 10 in accordance with some embodiments. In some embodiments, the semiconductor structure 10 includes a chip region 50, and an active region 52 including active devices formed in the chip region 50. The active region 52 may have various device elements. Examples of device elements may include, but are not limited to, transistors, diodes, and/or other applicable elements. Examples of the transistors may include, but are not limited to, metal oxide semiconductor field effect transistors (MOSFET), complementary metal oxide semiconductor (CMOS) transistors, high voltage transistors, high frequency transistors, p-channel and/or n-channel field effect transistors (PFETs/NFETs), or the like. Various processes may be performed to form the device elements, such as deposition, etching, implantation, photolithography, annealing, and other applicable processes.

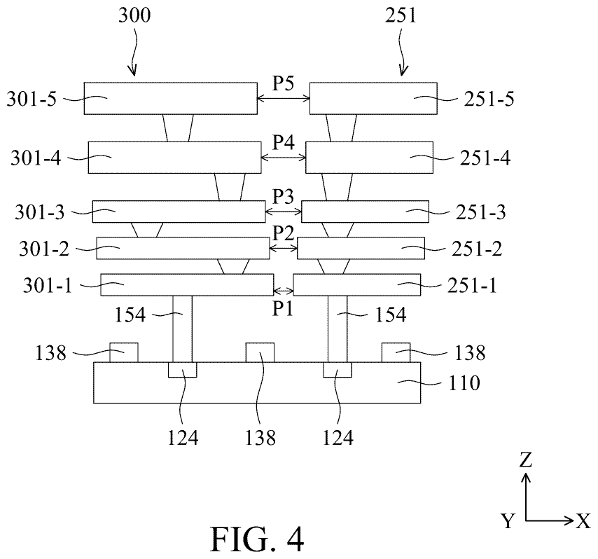

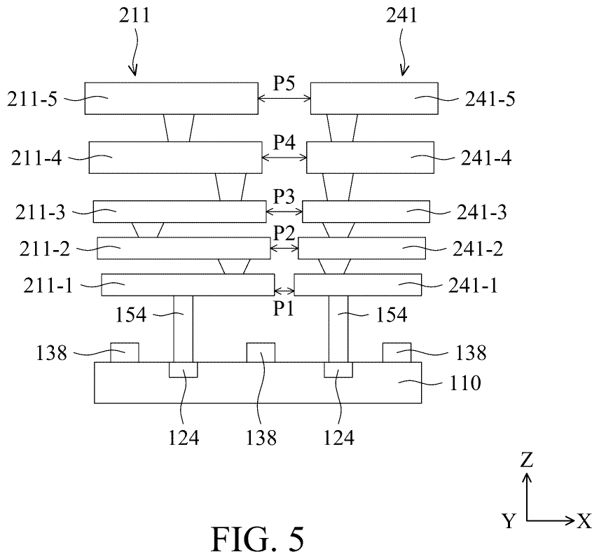

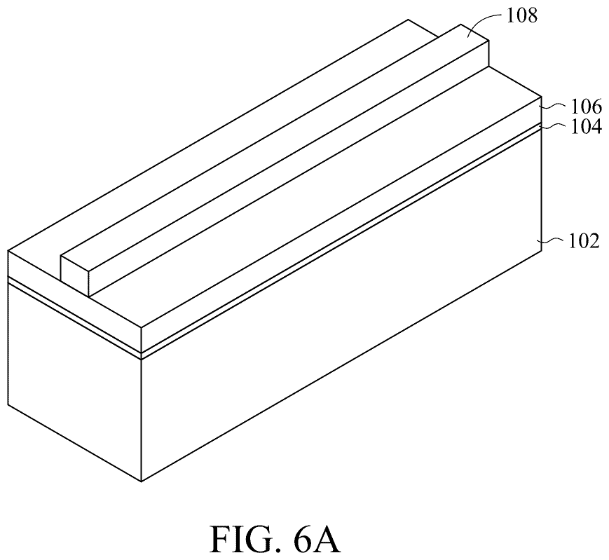

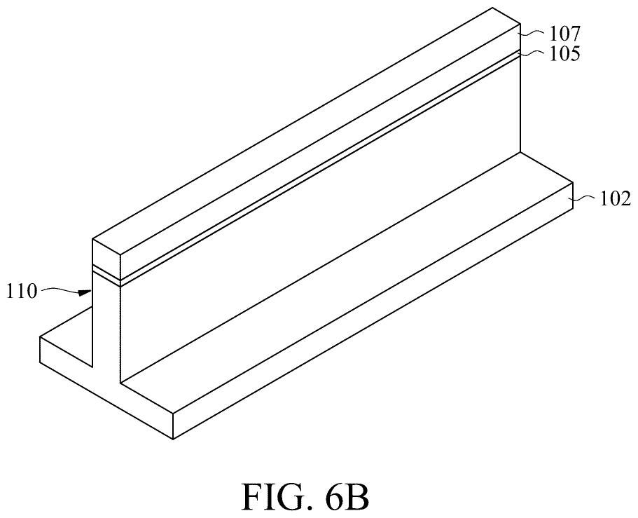

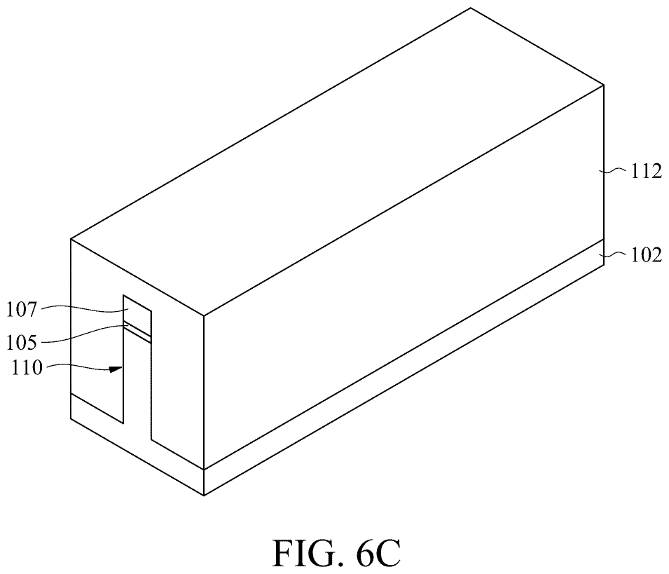

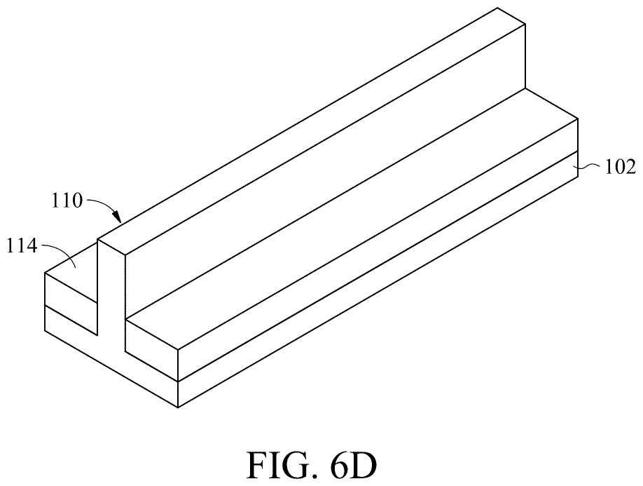

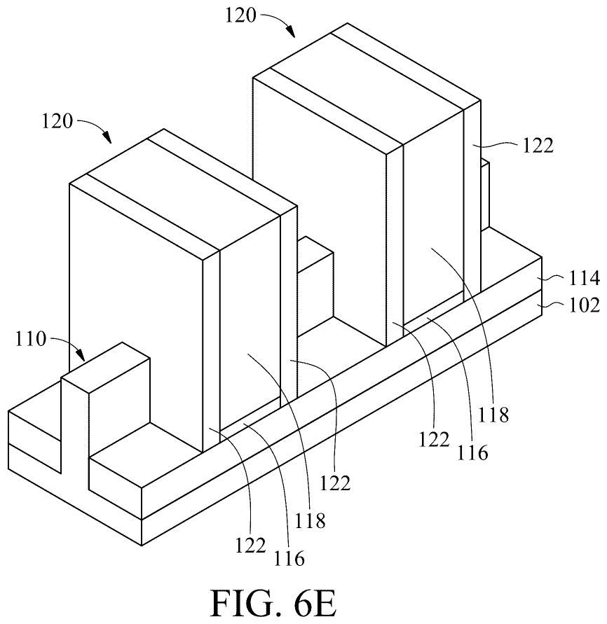

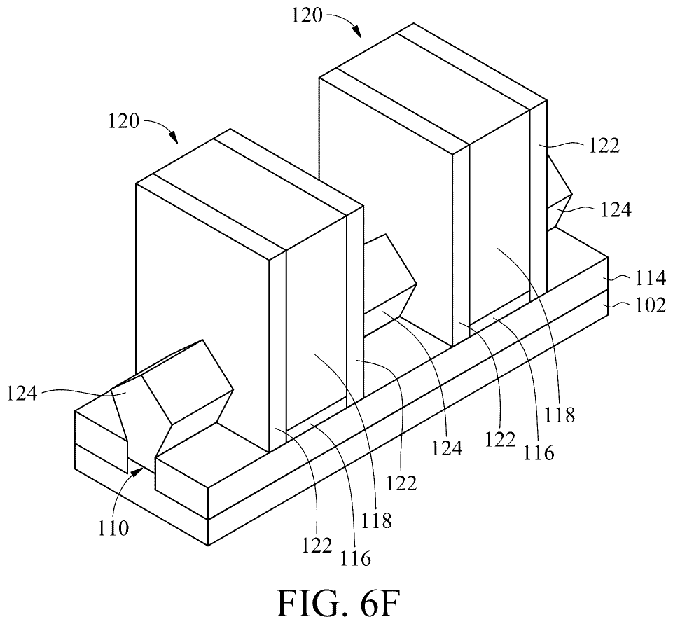

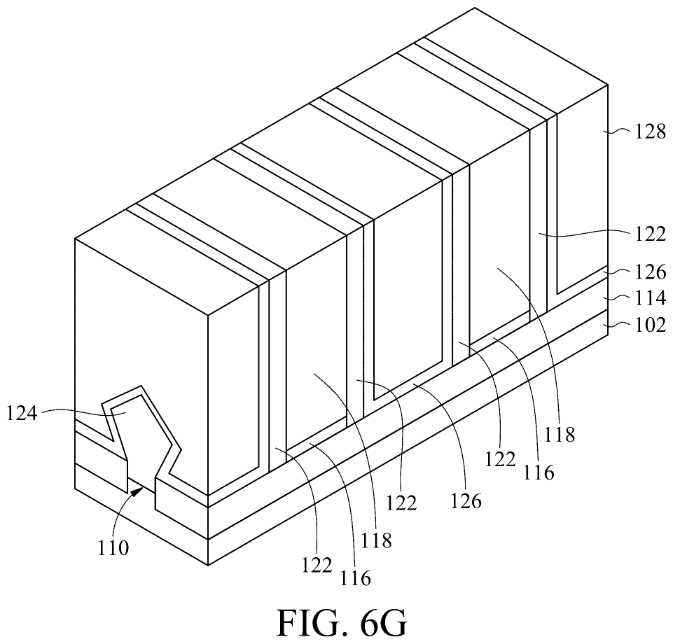

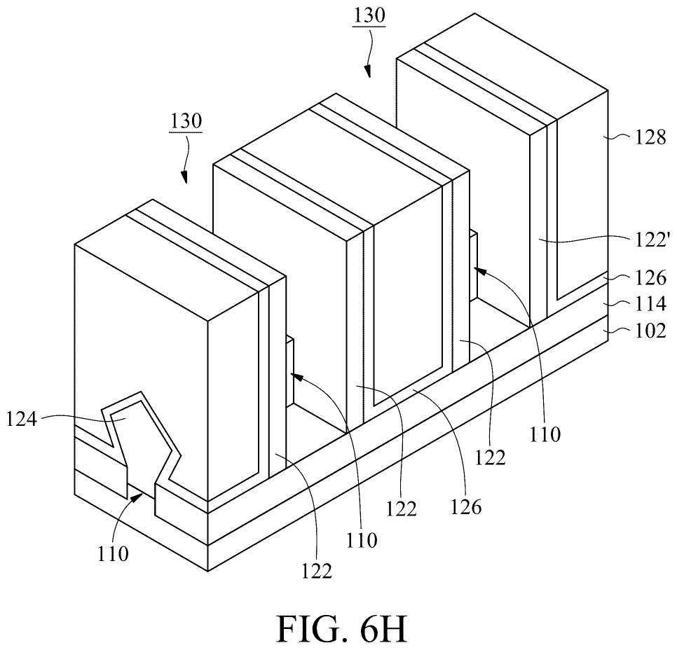

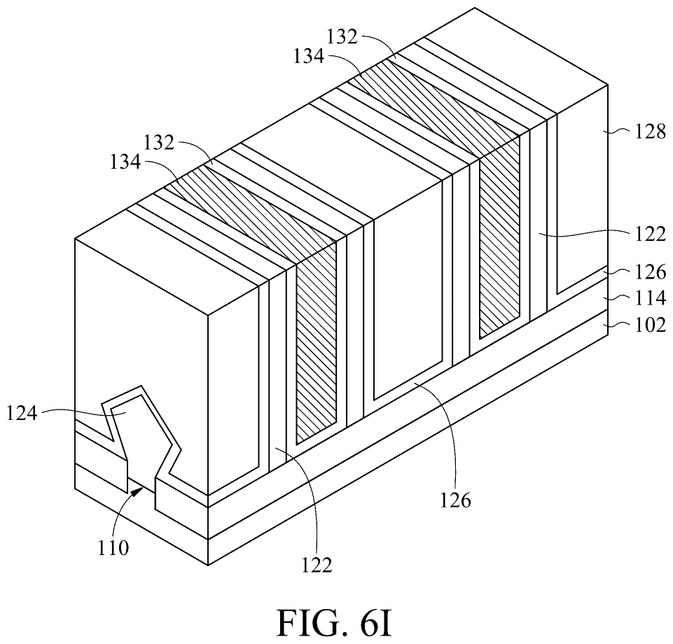

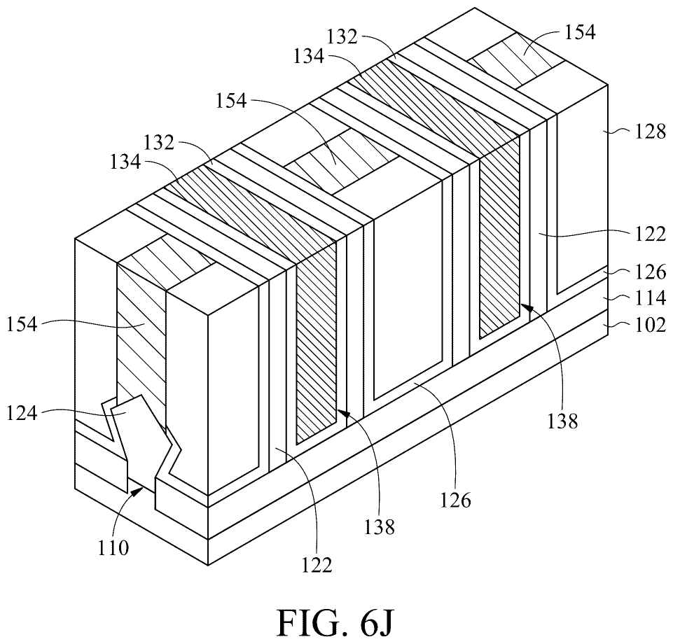

In some embodiments, an interconnect structure 55 in the chip region 50 and electrically connected to the active region 52 to form external connection to the active region 52. In addition, each of the scribe line regions 200 includes a testing region 210, and a plurality of testing patterns 211 and a testing device region 212 including testing device. The testing patterns 211 and the testing device region 212 may have electrical property that is similar to that of the interconnect structure 55 and the active region 52 in the chip 50. Accordingly, the testing patterns 211 and the testing device region 212 are formed for conducting performance test, reducing the risk of damage to the interconnect structure 55 and the active region 52 during these tests. Each of the scribe line regions 200 also includes a dicing region 220 around the testing region 210. The dicing region 220 has a blank band 230 without any pattern formed therein and a dummy band 240 adjacent to the testing region 210, and a plurality of dummy patterns 241 (referring to FIG. 5, for example) are formed in the dummy band 240 and electrically isolated from the testing patterns 211. In some embodiments, the dicing region 220 further has a dummy band 250 adjacent to the chip region 50, and a plurality of dummy patterns 251 (referring to FIG. 4, for example) are formed in the dummy band 250 and electrically isolated from the interconnect structure 55. In some embodiments, the blank band 230 is sandwiched between the dummy bands 240 and 250. With the arrangement of the dummy bands 240 and 250, which respectively include a stack of dummy patterns, the width (i.e., area) of the blank band 230 may be reduced to mitigate the risk of dishing issue in the dicing region 220 caused by repeating planarization processes during the formation of the semiconductor structure, thereby improving the overall surface topography. The seal ring 300 is disposed over one or more via contacts 154 on the substrate 102, such as disposed on active regions of the substrate 102. The detailed structure (including the via contacts 154) below the seal ring 300 will be further discussed in accompany with FIGS. 6A through 6J as follows. Over the via contacts 154, each of the seal ring 300 further includes multiple metal layers 301 stacked one over another and vertically connected by metal vias 302. Metal layers 301 and metal vias 302 may include copper, copper alloys, or other conductive materials and may be formed using damascene or dual damascene processes. Each of the metal layers 301 and the metal vias 302 may include a conductive barrier layer (such as TiN or TaN) surrounding a metal core (such as copper). In some embodiments, each of the metal layers 301 is formed into a ring or a ring-like structure (such as a substantially square ring) that surrounds the seal ring 300 and the chip region 50. In other words, each of the metal layers 301 is formed into a closed structure and extends along the edges of the area occupied by the seal rings 300 and the chip regions 50.

In the present embodiment, a ring or a ring-like structure refers to a closed structure, which may be rectangular, square, substantially rectangular, substantially square, or in other polygonal shapes. In some embodiments, the outer metal vias 302 (the metal vias 302 that are the closest and the furthest, respectively, from the seal rings 300 and the chip region 50) are formed into the shape of a ring. Thus, they are also referred to as via bars. The inner metal vias 302 are formed into discrete vias that form a line parallel to the outer metal vias 302. The metal layers 301, and the metal vias 302 are embedded in dielectric layers of the seal rings 300. The dielectric layers may include silicon oxide, silicon nitride, silicon oxynitride, low-k dielectric materials, extreme low-k (ELK) dielectric materials, or other suitable dielectric materials (for example, including silicon, oxygen, nitrogen, carbon, or other suitable isolation constituent), or combinations thereof.

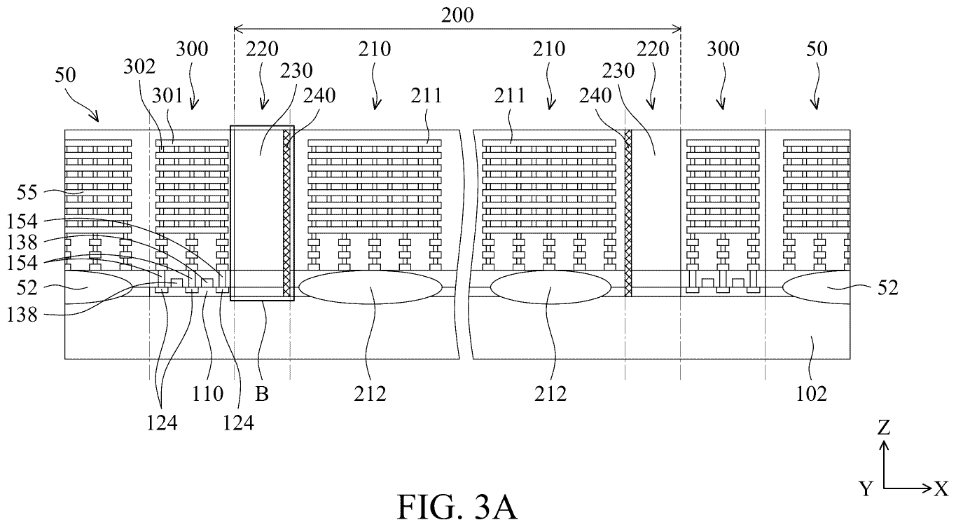

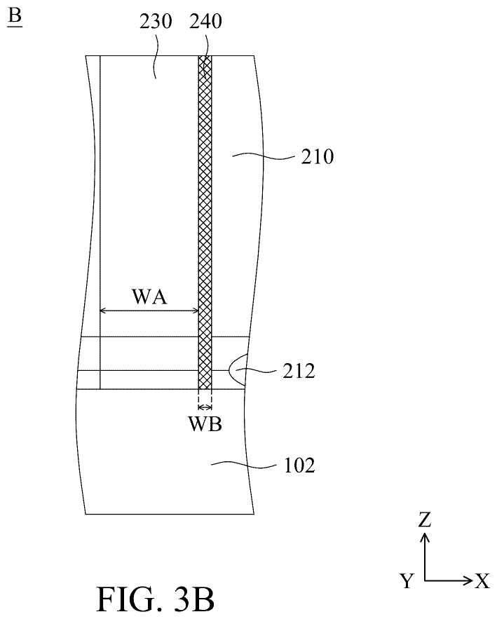

FIG. 2B illustrates an enlarged view of the region A shown in FIG. 2A in accordance with some embodiments. As shown in FIG. 2B, the width WC of the dummy band 250 is less than the width WB of the dummy band 240. In some embodiments, the width WA of the blank band 230 may be in a range from about 4 μm to about 10 μm. As a result, sufficient space may be provided for the plasma dicing during the separation process, and the empty region is not too large to cause dissing issue while performing a plurality of planarization process during formation of the semiconductor structure 10. In some embodiments, the width WC of the dummy band 250 may be less than about 0.5 times the width WA of the blank band 230. In some embodiments, the dummy band 250 may be omitted, which will be further discussed in the embodiment shown in FIGS. 3A and 3B as follows. In some embodiments, the width WB of the dummy band 240 may be in a range from about 0.3 times to about 1.5 times the width WA of the blank band 230. In this way, the dummy bands 240 and 250 may provide sufficient support to mitigate the dishing issue and improve the overall surface topography, and still leave sufficient space for disposing the chip regions 50.

FIG. 3A illustrates a partial cross-sectional view of the semiconductor structure 10 in accordance with some embodiments. FIG. 3B illustrates an enlarged view of the region B shown in FIG. 3A in accordance with some embodiments. It should be noted that the semiconductor structure 10 shown in this embodiment may include portions or elements that are the same as those of the semiconductor structure 10 shown in FIGS. 2A and 2B. These portions or elements will be denoted by the same numerals, and for the sake of brevity, will not be discussed in detail as follows. As shown in FIGS. 3A and 3B, the dummy band 250 is omitted and the overall width of the dicing region 220 may be reduced. Since the seal ring 300 has a certain width (for example, much wider than the dummy band 250) for protecting the chip regions 50, the dummy band 250 can be omitted and the chip regions 50 can still be well-protected from damage during the separation process. In this way, the occupied area of the scribe line regions 200 can be decreased and more chip regions 50 may be disposed on single wafer, improving the yield of the semiconductor structure.

FIG. 4 illustrates an enlarged view of the dummy band 250 and the seal ring 300 shown in FIGS. 2A and 2B in accordance with some embodiments. As shown in FIG. 4, the dummy band 250 shown in FIGS. 2A and 2B includes the dummy patterns 251, and the dummy patterns 251 includes a plurality of sub-layers, including a first sub-layer 251-1, a second sub-layer 251-2, a third sub-layer 251-3, a fourth sub-layer 251-4, and a fifth sub-layer 251-5. Similarly, the seal ring 300 also includes a plurality of sub-layers, including a first sub-layer 301-1, a second sub-layer 301-2, a third sub-layer 301-3, a fourth sub-layer 301-4, and a fifth sub-layer 301-5. It should be noted that the line width of the sub-layers of the dummy patterns 251 may be different, which makes the spacing between the sub-layers of the dummy patterns 251 and the sub-layers of the seal ring 300 varies in the normal direction (for example, the Z direction) of the substrate 102. To be more specific, the spacing P1 between the first sub-layer 251-1 of the dummy patterns 251 and the first sub-layer 301-1 of the seal ring 300 is less than the spacing P2 between the second sub-layer 251-2 of the dummy patterns 251 and the second sub-layer 301-2 of the seal ring 300 as the line widths of the dummy patterns 251 and the seal ring 300 increase for the upper sub-layers. For example, the spacing P1 between the first sub-layer 251-1 and the first sub-layer 301-1 may be in a range from about 10 nm to about 20 nm, depending upon the technology node and the design rule.

Accordingly, the spacing P2 between the second sub-layer 251-2 and the second sub-layer 301-2 is less than the spacing P3 between the third sub-layer 251-3 and the third sub-layer 301-3. The spacing P3 between the third sub-layer 251-3 and the third sub-layer 301-3 is less than the spacing P4 between the fourth sub-layer 251-4 and the fourth sub-layer 301-4. The spacing P4 between the fourth sub-layer 251-4 and the fourth sub-layer 301-4 is less than the spacing P5 between the fifth sub-layer 251-5 and the fifth sub-layer 301-5. For example, the spacing P5 between the fifth sub-layer 251-5 and the fifth sub-layer 301-5 may be in a range from about 1 μm to about 2 μm, depending upon the technology node and the design rule.

The dummy patterns 251 do not serve as a functional circuit and therefore are electrically insulated from the active region 52. However, during the operation of the semiconductor structure 10, electric charge may be accumulated in the dummy patterns 251, causing the risk of burnout. In some embodiments, the dummy patterns 251 are grounded that the via contact 154. In this way, the accumulated electric charge may be discharged and therefore the risk of burnout can be minimized. In some embodiments, the dummy patterns 251 are formed over the via contact 154. As a result, the portion of the dicing region 220 may have the pattern density similar to that of the seal ring 300 or the chip region 50. Therefore, while performing the planarization processes, the surface topography of the semiconductor structure 10 (excluding the blank band 230) may be more uniform, reducing the risk of the dishing issue, which may cause misalignment or some other defects during the manufacturing process of the semiconductor structure 10. In some embodiments, the dummy patterns 251 are formed over the metal gate structure 138. Since the S/D structure 124 and the metal gate structure 138 directly below the dummy patterns 251 are not serve as a functional circuit, the S/D structure 124 may be referred to as “the dummy S/D structure,” and the metal gate structure 138 may be referred to as “the dummy metal gate structure.”FIG. 5 illustrates an enlarged view of the dummy band 240 and the testing region 210 shown in FIGS. 2A and 2B in accordance with some embodiments. As shown in FIG. 5, the dummy patterns 241 includes a plurality of sub-layers, including a first sub-layer 241-1, a second sub-layer 241-2, a third sub-layer 241-3, a fourth sub-layer 241-4, and a fifth sub-layer 241-5. Similarly, the testing patterns 211 also includes a plurality of sub-layers, including a first sub-layer 211-1, a second sub-layer 211-2, a third sub-layer 211-3, a fourth sub-layer 211-4, and a fifth sub-layer 211-5. It should be noted that the line width of the sub-layers of the dummy patterns 241 may be different, which makes the spacing between the sub-layers of the dummy patterns 241 and the sub-layers of the testing patterns 211 varies in the normal direction (for example, the Z direction) of the substrate 102. To be more specific, the spacing P1 between the first sub-layer 241-1 of the dummy patterns 241 and the first sub-layer 211-1 of the testing patterns 211 is less than the spacing P2 between the second sub-layer 241-2 of the dummy patterns 241 and the second sub-layer 211-2 of the testing patterns 211 as the line widths of the dummy patterns 241 and the testing patterns 211 increase for the upper sub-layers. For example, the spacing P1 between the first sub-layer 241-1 and the first sub-layer 211-1 may be in a range from about 10 nm to about 20 nm, depending upon the technology node and the design rule. In some embodiments, the height of the dummy patterns 241 is substantially equal to a height of the testing patterns 211. However, the present disclosure is not limited thereto.

Accordingly, the spacing P2 between the second sub-layer 241-2 and the second sub-layer 211-2 is less than the spacing P3 between the third sub-layer 241-3 and the third sub-layer 211-3. The spacing P3 between the third sub-layer 241-3 and the third sub-layer 211-3 is less than the spacing P4 between the fourth sub-layer 241-4 and the fourth sub-layer 211-4. The spacing P4 between the fourth sub-layer 241-4 and the fourth sub-layer 211-4 is less than the spacing P5 between the fifth sub-layer 241-5 and the fifth sub-layer 211-5. For example, the spacing P5 between the fifth sub-layer 241-5 and the fifth sub-layer 211-5 may be in a range from about 1 μm to about 2 μm, depending upon the technology node and the design rule.

FIGS. 6A through 6J illustrates cross-sectional views of intermediate steps during a process for fabricating a semiconductor structure in accordance with some embodiments. A substrate 102 is provided, as shown in FIG. 6A in accordance with some embodiments. The substrate 102 may be a semiconductor wafer such as a silicon wafer. Alternatively or additionally, the substrate 102 may include elementary semiconductor materials, compound semiconductor materials, and/or alloy semiconductor materials. Examples of the elementary semiconductor materials may include, but are not limited to, crystal silicon, polycrystalline silicon, amorphous silicon, germanium, and/or diamond. Examples of the compound semiconductor materials may include, but are not limited to, silicon carbide, gallium arsenic, gallium phosphide, indium phosphide, indium arsenide, and/or indium antimonide. Examples of the alloy semiconductor materials may include, but are not limited to, SiGe, GaAsP, AlInAs, AlGaAs, GaInAs, GaInP, and/or GaInAsP. In some embodiments, the substrate 102 includes an epitaxial layer. For example, the substrate 102 has an epitaxial layer overlying a bulk semiconductor.

Afterwards, a dielectric layer 104 and a mask layer 106 are formed over the substrate 102, and a patterned photoresist layer 108 is formed over the mask layer 106, as shown in FIG. 6A in accordance with some embodiments. The patterned photoresist layer 108 may be formed by a deposition process and a patterning process.

The deposition process for forming the patterned photoresist layer 108 may include a chemical vapor deposition (CVD) process, a high-density plasma chemical vapor deposition (HDPCVD) process, a spin-on process, a sputtering process, or another applicable process. The patterning process for forming the patterned photoresist layer 108 may include a photolithography process and an etching process. The photolithography process may include photoresist coating (e.g., spin-on coating), soft baking, mask aligning, exposure, post-exposure baking, developing the photoresist, rinsing and drying (e.g., hard baking). The etching process may include a dry etching process or a wet etching process.

Moreover, the dielectric layer 104 may be a buffer layer between the substrate 102 and the mask layer 106. In some embodiments, the dielectric layer 104 is used as a stop layer when the mask layer 106 is removed. The dielectric layer 104 may be made of silicon oxide. The mask layer 106 may be made of silicon oxide, silicon nitride, silicon oxynitride, or another applicable material. In some other embodiments, more than one mask layer 106 is formed over the dielectric layer 104.

The dielectric layer 104 and the mask layer 106 may be formed by deposition processes, which may include a chemical vapor deposition (CVD) process, a high-density plasma chemical vapor deposition (HDPCVD) process, a spin-on process, a sputtering process, or another applicable process.

After the patterned photoresist layer 108 is formed, the dielectric layer 104 and the mask layer 106 are patterned by using the patterned photoresist layer 108 as a mask, shown in FIG. 6B in accordance with some embodiments. As a result, a patterned dielectric layer 105 and a patterned mask layer 107 are obtained. Afterwards, the patterned photoresist layer 108 is removed.

Next, an etching process is performed on the substrate 102 to form a channel structure 110 by using the patterned dielectric layer 105 and the patterned mask layer 107 as a mask. The etching process may be a dry etching process or a wet etching process.

In some embodiments, the substrate 102 is etched by a dry etching process. The dry etching process includes using a fluorine-based etchant gas, such as SF₆, CₓF_{y}, NF₃ or a combination thereof. The etching process may be a time-controlled process, and continue until the channel structure 110 reaches a predetermined height. In some other embodiments, the channel structure 110 has a width that gradually increases from the top portion to the lower portion.

After the channel structure 110 is formed, an insulating layer 112 is formed to cover the channel structure 110, the patterned pad layer 105, and the patterned mask layer 107 over the substrate 102, as shown in FIG. 6C in accordance with some embodiments. In some embodiments, the insulating layer 112 is made of silicon oxide, silicon nitride, silicon oxynitride, fluoride-doped silicate glass (FSG), or another low-k dielectric material. The insulating layer 112 may be deposited by a chemical vapor deposition (CVD) process, a spin-on-glass process, or another applicable process.

Next, the insulating layer 112 is thinned or planarized to expose the top surface of the patterned mask layer 107. In some embodiments, the insulating layer 112 is thinned by a chemical mechanical polishing (CMP) process. Afterwards, the patterned dielectric layer 105 and the patterned mask layer 107 are removed.

After the patterned dielectric layer 105 and the patterned mask layer 107 are removed, an upper portion of the insulating layer 112 is removed to form an isolation structure 114, as shown in FIG. 6D in accordance with some embodiments. The isolation structure 114 may be a shallow trench isolation (STI) structure surrounding the channel structure 110. In some embodiments, a portion of the channel structure 110 is embedded in the isolation structure 114. More specifically, a lower portion of the channel structure 110 is surrounded by the isolation structure 114, while an upper portion of the channel structure 110 protrudes from the isolation structure 114. The isolation structure 114 is configured to prevent electrical interference or crosstalk.

After the isolation structure 114 is formed, dummy gate structures 120 are formed across the channel structure 110 and extend over the isolation structure 114, as shown in FIG. 1E in accordance with some embodiments. In some embodiments, each of the dummy gate structures 120 includes a dummy gate dielectric layer 116 and a dummy gate electrode layer 118 formed over the dummy gate dielectric layer 116. After the dummy gate structures 120 are formed, gate spacers 122 are formed on opposite sidewalls of each of the dummy gate structures 120. Each of the gate spacers 122 may be a single layer or multiple layers.

In order to improve the speed of the FinFET device structure 100a, the gate spacers 122 are made of low-k dielectric materials. In some embodiments, the low-k dielectric materials have a dielectric constant (k value) less than about 4. Examples of low-k dielectric materials include, but are not limited to, silicon oxide, silicon nitride, silicon carbonitride (SiCN), silicon oxide carbonitride (SiOCN), fluorinated silica glass (FSG), carbon doped silicon oxide, amorphous fluorinated carbon, parylene, bis-benzocyclobutenes (BCB), or polyimide.

In some other embodiments, the gate spacers 122 are made of an extreme low-k (ELK) dielectric material with a dielectric constant (k) less than about 2.5. In some embodiments, the ELK dielectric materials include carbon doped silicon oxide, amorphous fluorinated carbon, parylene, bis-benzocyclobutenes (BCB), polytetrafluoroethylene (PTFE) (Teflon), or silicon oxycarbide polymers (SiOC). In some embodiments, ELK dielectric materials include a porous version of an existing dielectric material, such as hydrogen silsesquioxane (HSQ), porous methyl silsesquioxane (MSQ), porous polyarylether (PAE), porous SiLK, or porous silicon oxide (SiO₂).

In addition, in some embodiments, the gate spacers 122 include air gaps (not shown) to further reduce their k value, such that the capacitances between the gate structures (formed subsequently) and the contacts (formed subsequently) electrically connected to the S/D structure (formed subsequently) may be reduced.

Afterwards, source/drain (S/D) structures 124 are formed over the channel structure 110, as shown in FIG. 6F in accordance with some embodiments. Source/drain region(s) may refer to a source or a drain, individually or collectively dependent upon the context. In some embodiments, portions of the channel structure 110 adjacent to the dummy gate structures 120 are recessed to form recesses at two sides of the channel structure 110, and a strained material is grown in the recesses by an epitaxial (epi) process to form the S/D structures 124. Accordingly, the S/D structures 124 may also be referred to as “epitaxial structure” in the present disclosure. In addition, the lattice constant of the strained material may be different from the lattice constant of the substrate 102. In some embodiments, the S/D structures 124 include Ge, SiGe, InAs, InGaAs, InSb, GaAs, GaSb, InAlP, InP, or the like.

After the source/drain (S/D) structures 124 are formed, a contact etch stop layer (CESL) 126 is formed over the substrate 102, and an inter-layer dielectric (ILD) structure 128 is formed over the CESL 126. More specifically, the CESL 126 is formed over the S/D structures 124, the isolation structure 114, and the sidewalls of the gate spacers 122. In some embodiments, the CESL 126 is made of silicon nitride, silicon oxynitride, and/or other applicable materials. Moreover, the CESL 126 may be formed by plasma enhanced CVD, low-pressure CVD, atomic layer deposition (ALD), or other applicable processes.

In some embodiments, the ILD structure 128 includes multilayers made of multiple dielectric materials, such as silicon oxide, silicon nitride, silicon oxynitride, phosphosilicate glass (PSG), borophosphosilicate glass (BPSG), low-k dielectric material, and/or other applicable dielectric materials. Examples of the low-k dielectric materials include, but are not limited to, fluorinated silica glass (FSG), carbon doped silicon oxide, amorphous fluorinated carbon, parylene, bis-benzocyclobutenes (BCB), or polyimide. In addition, the ILD structure 128 may be formed by chemical vapor deposition (CVD), physical vapor deposition, (PVD), atomic layer deposition (ALD), spin-on coating, or another applicable process.

Afterwards, a planarizing process is performed on the ILD structure 128 until the top surfaces of the dummy gate structures 120 are exposed, as shown in FIG. 6G in accordance with some embodiments. After the planarizing process, the top surfaces of the dummy gate structures 120 may be substantially level with the top surfaces of the gate spacers 122 and the ILD structure 128. In some embodiments, the planarizing process includes a grinding process, a chemical mechanical polishing (CMP) process, an etching process, another applicable process, or a combination thereof.

Next, the dummy gate structures 120 are removed to form trenches 130 in the ILD structure 128, as shown in FIG. 6H in accordance with some embodiments. More specifically, each of the trenches 130 is formed between each pair of the gate spacers 122, and the channel structure 110 is exposed by the trenches 130. The dummy gate dielectric layer 116 and the dummy gate electrode layer 118 are removed by an etching process, such as a dry etching process or a wet etching process.

After the trenches 130 are formed, gate dielectric layers 132 and gate electrode layers 134 are formed in the trenches 130, as shown in FIG. 6I in accordance with some embodiments. More specifically, the gate electrode layers 134 are formed over the gate dielectric layers 132, and sidewalls of the gate electrode layers 132 may be covered by the gate dielectric layers 132. In addition, work function layers (not shown) may be formed between each of the gate dielectric layers 132 and each of the gate electrode layers 134. In some embodiments, the metal gate structures 138 includes the gate dielectric layers 132, the gate electrode layers 134 and the work function layers (not shown).

Each of the gate dielectric layers 132 may be a single layer or multiple layers. In some embodiments, the gate dielectric layers 132 are made of silicon oxide, silicon nitride, silicon oxynitride (SiON), dielectric material(s) with high dielectric constant (high-k), or a combination thereof. In some embodiments, the gate dielectric layers 132 are deposited by a plasma enhanced chemical vapor deposition (PECVD) process or a spin coating process.

Moreover, the gate electrode layers 134 are made of a conductive material such as aluminum (Al), copper (Cu), tungsten (W), titanium (Ti), tantalum (Ta), or another applicable material, in accordance with some embodiments. The gate electrode layers 134 may be formed by a deposition process, such as a chemical vapor deposition (CVD) process, a physical vapor deposition (PVD) process, an atomic layer deposition (ALD) process, a high density plasma CVD (HDPCVD) process, a metal organic CVD (MOCVD) process, or a plasma enhanced CVD (PECVD) process.

The work function layers may be made of metal materials, and the metal materials may include N-work-function metal or P-work-function metal. The N-work-function metal may include tungsten (W), copper (Cu), titanium (Ti), silver (Ag), aluminum (Al), titanium aluminum alloy (TiAl), titanium aluminum nitride (TiAlN), tantalum carbide (TaC), tantalum carbon nitride (TaCN), tantalum silicon nitride (TaSiN), manganese (Mn), zirconium (Zr) or a combination thereof. The P-work-function metal may include titanium nitride (TiN), tungsten nitride (WN), tantalum nitride (TaN), ruthenium (Ru) or a combination thereof.

Then, as shown in FIG. 6J, a via contact 154 is formed over the S/D structures 124. It should be noted that the via contacts 154 are electrically connected to the S/D structures 124. In some embodiments, the via contacts 154 are made of tungsten (W), cobalt (Co), titanium (Ti), aluminum (Al), copper (Cu), tantalum (Ta), platinum (Pt), molybdenum (Mo), silver (Ag), manganese (Mn), zirconium (Zr), ruthenium (Ru), or another applicable material. In some embodiments, the via contacts 154 are formed by a deposition process, a planarization process and an etching process. The deposition process may include a chemical vapor deposition (CVD) process, a physical vapor deposition (PVD) process, an atomic layer deposition (ALD) process, a plating process, or another applicable process.

It should be noted that the fin field-effect transistor (FinFET) structure merely serve as an example, any front-end-of-line (FEOL) process may be adopted to form desired structure, such as gate-all-around (GAA) structure, planar field-effect transistor (FET) structure, etc.

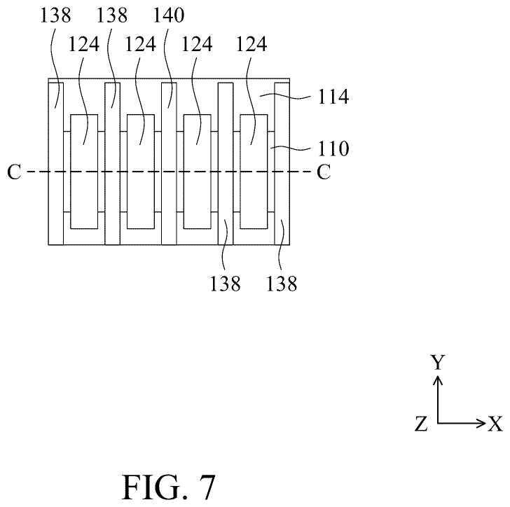

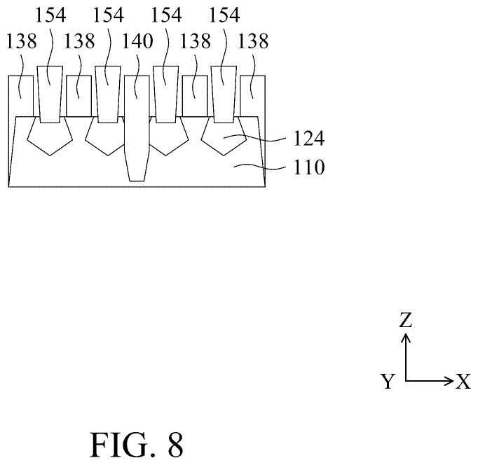

Additional isolation structures may also be applied to the semiconductor structures described above. FIG. 7 illustrates a schematic top view of the semiconductor structure in accordance with some embodiments. FIG. 8 illustrates a partial cross-sectional view of the semiconductor structure in accordance with some embodiments. As shown in FIG. 7 and FIG. 8, an isolation structure 140 may be formed substantially parallel to the metal gate structure 138. For example, one of the metal gate structure 138 and the channel structure 110 may be removed and replaced by the isolation structure 140. The isolation structure 140 is made of a dielectric material such as silicon nitride (SiN) or any other suitable material. In some embodiments, an oxide liner, such as silicon oxide, is provided at a lower portion of the isolation structure 140. The isolation structure 140 may be disposed in the chip region 50 so as to provide the desired scaling and increased density for multi-gate devices in advanced technology nodes calls for scaling of the contacted poly pitch (CPP) (or “gate pitch”). The isolation structure 140 is also provided below the dummy patterns 241 and/or 251 for uniform surface topography.

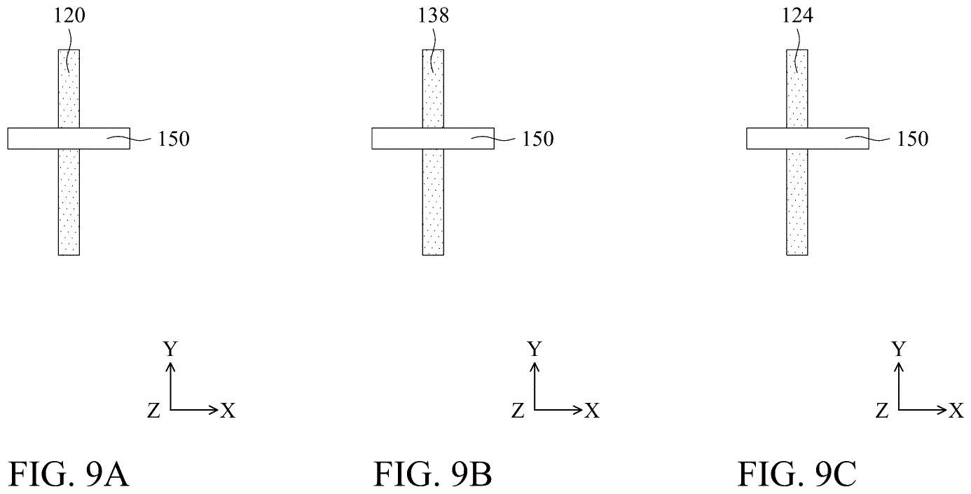

FIGS. 9A through 9C illustrates schematic views of other types of the isolation structures in the semiconductor structure in accordance with some embodiments. As shown in FIG. 9A, an isolation structure 150 may be formed over the isolation structure 114 and directly below the dummy patterns 241 and/or 251. In the present embodiments, the isolation structure 150 passes through the dummy gate structures 120, and the extending direction of the isolation structure 150 is substantially perpendicular to the extending direction of the dummy gate structures 120. The dummy gate structure 120 may be replaced by the metal gate structure 138 afterwards as described previously. As shown in FIG. 9B, an isolation structure 150 may be formed over the isolation structure 114 and directly below the dummy patterns 241 and/or 251. In some embodiments, the isolation structure 150 passes through the metal gate structure 138, and the extending direction of the isolation structure 150 is substantially perpendicular to the extending direction of the metal gate structure 138. As shown in FIG. 9C, an isolation structure 150 may be formed over the isolation structure 114 and directly below the dummy patterns 241 and/or 251. In some embodiments, the isolation structure 150 passes through the via contact 154, and the extending direction of the isolation structure 150 is substantially perpendicular to the extending direction of the via contact 154.

It should be noted that these isolation structures 150 may be disposed in across the semiconductor structure 10 excluding the blank band 230 for the separation. As a result, the pattern density may be substantially the same across the semiconductor structure 10 excluding the blank band 230. Therefore, while performing the planarization processes, the surface topography of the semiconductor structure 10 (excluding the blank band 230) may be more uniform, reducing the risk of the dishing issue, which may cause misalignment or some other defects during the manufacturing process of the semiconductor structure 10.

Embodiments of methods for fabricating the semiconductor structure are provided. The method includes forming a plurality of scribe line regions among the chips on the substrate. The scribe line regions each include a testing region and a dicing region around the test region. The dicing region has a dummy band adjacent to the testing region, and a plurality of dummy patterns are formed in the dummy band and electrically isolated from the testing region. As a result, the dummy patterns in the dummy band may help to improve the surface topography after preforming planarization processes during the manufacturing process of the semiconductor structure. In addition, the dummy patterns are grounded through the via contacts so as to reduce the risk of burnout. Furthermore, dummy metal gate structures or dummy S/D structure (optionally with cut patterns) may be disposed below the dummy patterns in the dicing region for uniform surface topography.

In some embodiments, a method for fabricating a semiconductor structure is provided. The method includes providing a plurality of chip regions on a substrate. The method includes forming a plurality of scribe line regions among the chips on the substrate. The scribe line regions each include a testing region having a plurality of testing patterns and a dicing region around the test region. The dicing region has a dummy band adjacent to the testing region, and a plurality of dummy patterns are formed in the dummy band and electrically isolated from the testing patterns. The method also includes separating the chip regions along the dicing region of the scribe line regions.

In some embodiments, a method for fabricating a semiconductor structure is provided. The method includes providing a plurality of chip regions on a substrate. The method includes forming a seal ring around each of the chip regions. The method includes forming a plurality of scribe line regions among the chip regions on the substrate. The scribe line regions includes a dicing region around the seal ring, the dicing region has a first dummy band adjacent to the seal ring, and a plurality of first dummy patterns are formed in the first dummy band and electrically isolated from the seal ring. The method also includes separating the chip regions.

In some embodiments, a method for fabricating a semiconductor structure is provided. The method includes forming an active region, a plurality of channel structures, and a testing device region over a substrate. The channel structures are located between the active region and the testing device region. The method includes forming a first isolation structure among the channel structures. The method includes forming a gate structure and an epitaxial structure over the channel structures. The method includes forming a via contact over the epitaxial structure. The method includes forming a plurality of dummy patterns over the via contact. The dummy patterns are electrically isolated from the active region and the testing device region, and are grounded through the via contact. The method also includes separating the active region and the testing device region along a blank band of a scribe line region. The blank band is spaced apart from the dummy patterns.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method for fabricating a semiconductor structure, comprising:
providing a plurality of chip regions on a substrate;
forming a plurality of scribe line regions among the chips on the substrate, wherein the scribe line regions each comprise:
a testing region having a plurality of testing patterns; and
a dicing region around the test region, wherein the dicing region has a dummy band adjacent to the testing region, and a plurality of dummy patterns are formed in the dummy band and electrically isolated from the testing patterns; and
separating the chip regions along the dicing region of the scribe line regions.

2. The method as claimed in claim 1, wherein the dicing region comprises a blank band adjacent to the dummy band, and the blank band is free from the dummy patterns.

3. The method as claimed in claim 2, wherein the dummy band is grounded through a via contact in the substrate.

4. The method as claimed in claim 3, further comprising:
forming an epitaxial structure in an isolation structure over the substrate, wherein the via contact is formed over the epitaxial structure.

5. The method as claimed in claim 1, wherein a height of the dummy patterns is substantially equal to a height of the testing patterns.

6. The method as claimed in claim 5, wherein a spacing between the dummy patterns and the testing patterns varies in a normal direction of the substrate.

7. A method for fabricating a semiconductor structure, comprising:
providing a plurality of chip regions on a substrate;
forming a seal ring around each of the chip regions;
forming a plurality of scribe line regions among the chip regions on the substrate, wherein the scribe line regions comprise a dicing region around the seal ring, wherein the dicing region has a first dummy band adjacent to the seal ring, and a plurality of first dummy patterns are formed in the first dummy band and electrically isolated from the seal ring; and
separating the chip regions.

8. The method as claimed in claim 7, wherein the scribe line regions comprise a testing region having a plurality of testing patterns and adjacent to the dicing region, the dicing region having a second dummy band adjacent to the testing region, and a plurality of second dummy patterns are formed in the second dummy band and electrically isolated from the testing patterns.

9. The method as claimed in claim 8, wherein a width of the first dummy band is less than or equal to a width of the second dummy band.

10. The method as claimed in claim 8, wherein the dicing region comprises a blank band between the first dummy band and the second dummy band, and the blank band is free from the first dummy patterns and the second dummy patterns.

11. The method as claimed in claim 10, wherein a width of the first dummy band is less than a width of the blank band.

12. The method as claimed in claim 7, further comprising:
forming a plurality of via contacts in the substrate, wherein the first dummy patterns and the second dummy patterns are grounded through the via contacts.

13. The method as claimed in claim 7, further comprising:
forming a plurality of metal patterns in the seal ring, wherein a spacing between the first dummy patterns and the metal patterns varies in a normal direction of the substrate.

14. A method for fabricating a semiconductor structure, comprising:
forming an active region, a plurality of channel structures, and a testing device region over a substrate, wherein the channel structures are located between the active region and the testing device region;
forming a first isolation structure among the channel structures;
forming a gate structure and an epitaxial structure over the channel structures;
forming a via contact over the epitaxial structure;
forming a plurality of dummy patterns over the via contact, wherein the dummy patterns are electrically isolated from the active region and the testing device region, and are grounded through the via contact; and
separating the active region and the testing device region along a blank band of a scribe line region, wherein the blank band is spaced apart from the dummy patterns.

15. The method as claimed in claim 14, further comprising:
forming an interconnect structure over the active region to form a chip region, wherein the interconnect structure is electrically isolated from the dummy patterns.

16. The method as claimed in claim 15, wherein a spacing between the dummy patterns and the interconnect structure varies in a normal direction of the substrate.

17. The method as claimed in claim 14, further comprising:
forming a plurality of testing patterns over the testing device region in the scribe line region, wherein the testing patterns are electrically isolated from the dummy patterns.

18. The method as claimed in claim 17, wherein a spacing between the dummy patterns and the testing patterns varies in a normal direction of the substrate.

19. The method as claimed in claim 14, further comprising:
forming a plurality of second isolation structures over the first isolation structure and directly below the dummy patterns, wherein one of the second isolation structures passes through the gate structure, and an extending direction of the second isolation structures is substantially perpendicular to an extending direction of the gate structure.

20. The method as claimed in claim 14, further comprising:
forming a plurality of second isolation structures over the first isolation structure and directly below the dummy patterns, wherein one of the second isolation structures passes through the via contact, and an extending direction of the second isolation structures is substantially perpendicular to an extending direction of the via contact.
